(19) United States
(12) Patent Application Publication
(10) Pub. No.: US 2026/0369958 A1
(43) Pub. Date: Nov. 19, 2026

(54) Nitride Semiconductor Laser Element

(71) Applicant: NICHIA CORPORATION, Anan-shi, Tokushima (JP)

(72) Inventors: Teruyuki MORITO, Anan-shi, Tokushima (JP); Tomonori MORIZUMI, Anan-shi, Tokushima (JP)

(21) Appl. No.: 18/733,822

(22) Filed: Jun. 4, 2024

(30) Foreign Application Priority Data
Jun. 5, 2023 (JP) 2023-092120

(51) Int. Cl. H01S 5/028

(52) U.S. Cl. CPC H01S 5/028

(57) ABSTRACT

A nitride semiconductor laser element includes a nitride semiconductor layered body and a protective film. The nitride semiconductor layered body includes a first nitride semiconductor layer, a second nitride semiconductor layer, and an active layer. The nitride semiconductor layered body defines a light emission side end surface and a light reflection side end surface that intersect with a surface of the active layer on a side of the second nitride semiconductor layer. The protective film is arranged on the light emission side end surface. The protective film includes a first film made of an oxide film containing aluminum and/or gallium, a second film made of a nitride film, a first Al-containing film containing aluminum and oxygen, a first silicon oxide film, a second Al-containing film containing aluminum and oxygen, and a second silicon oxide film. The second silicon oxide film is disposed on an outermost side of the protective film.

### CROSS-REFERENCE TO RELATED APPLICATIONS

The present application claims priority under 35 U.S.C. § 119 to Japanese Patent Application No. 2023-092120, filed Jun. 5, 2023, the content of which is hereby incorporated herein by reference in its entirety.

### BACKGROUND

The present disclosure relates to a nitride semiconductor laser element.

Recently, there have been proposed various light-emitting devices that include a semiconductor laser or the like as an excitation light source and provide illumination or the like using excitation light emitted from the excitation light source.

In such a light-emitting device, there has been proposed a nitride-based semiconductor laser element in which peeling of a protective film formed on a resonator surface is prevented (see, e.g., Japanese Patent Publication No. 2009-99959).

### SUMMARY

On the other hand, in a semiconductor laser for which a high output is particularly required, catastrophic optical damage (COD) is one of factors of limiting the high output. For further improvement in the output, reducing the likelihood of occurrence of the catastrophic optical damage has been required.

A nitride semiconductor laser element of one embodiment in the present disclosure includes a nitride semiconductor layered body and a protective film. The nitride semiconductor layered body includes a first nitride semiconductor layer having a first conductivity type, a second nitride semiconductor layer having a second conductivity type as a conductivity type different from the first conductivity type, and an active layer disposed between the first nitride semiconductor layer and the second nitride semiconductor layer. The nitride semiconductor layered body defines a light emission side end surface and a light reflection side end surface that intersect with a surface of the active layer on a side of the second nitride semiconductor layer. The protective film is arranged on the light emission side end surface. The protective film includes, in the order from a side of the light emission side end surface, a first film made of an oxide film containing aluminum and/or gallium, a second film made of a nitride film, a first Al-containing film containing aluminum and oxygen, a first silicon oxide film, a second Al-containing film containing aluminum and oxygen, and a second silicon oxide film. The second silicon oxide film is disposed on an outermost side of the protective film.

In the nitride semiconductor laser element of one embodiment of the present disclosure, the likelihood of occurrence of catastrophic optical damage can be reduced.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic perspective view of a nitride semiconductor laser element of an embodiment.

FIG. 1B is a schematic front view of FIG. 1A.

FIG. 1C is a schematic cross-sectional view taken along a line IC-IC in FIG. 1A.

FIG. 1D is a partially enlarged view illustrating an example of a protective film on a side of a light emission side end surface.

FIG. 2 is a high-resolution transmission electron microscope image of a protective film and its vicinity.

FIG. 3A is an electron diffraction image of a first Al-containing film.

FIG. 3B is an electron diffraction image of a second film.

FIG. 3C is an electron diffraction image of a first film.

FIG. 3D is an electron diffraction image of a nitride semiconductor layered body.

FIG. 4 is a cross-sectional view illustrating another example of the nitride semiconductor laser element.

FIG. 5 is a partially enlarged view illustrating an example of a protective film on a side of a light reflection side end surface.

### DETAILED DESCRIPTION

Embodiments of the present invention will be described below with reference to the drawings. Note that the embodiments described below exemplify a method for embodying a technical thought of the present invention, and the present invention is not specified to the embodiments described below. Further, in the following description, members having the same terms and reference signs represent the same members or members of the same quality, and the detailed description thereof will be omitted as appropriate.

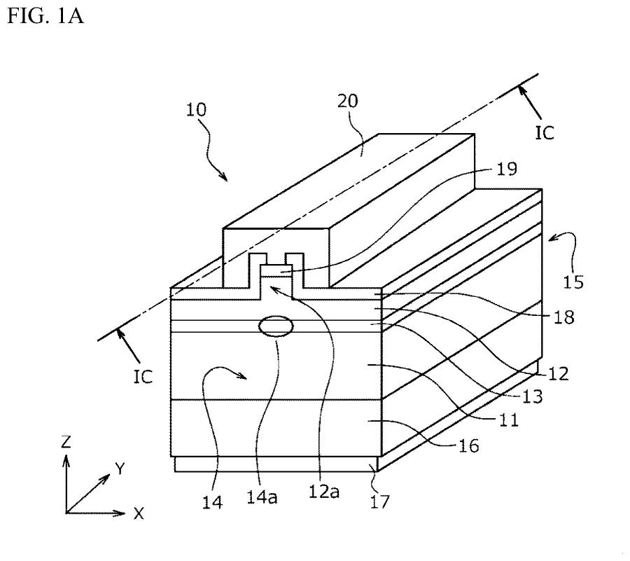

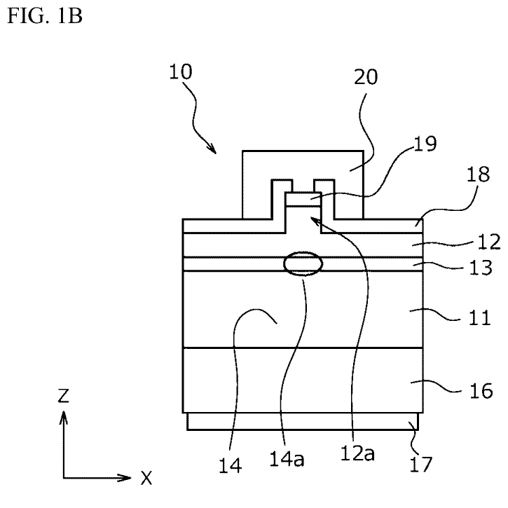

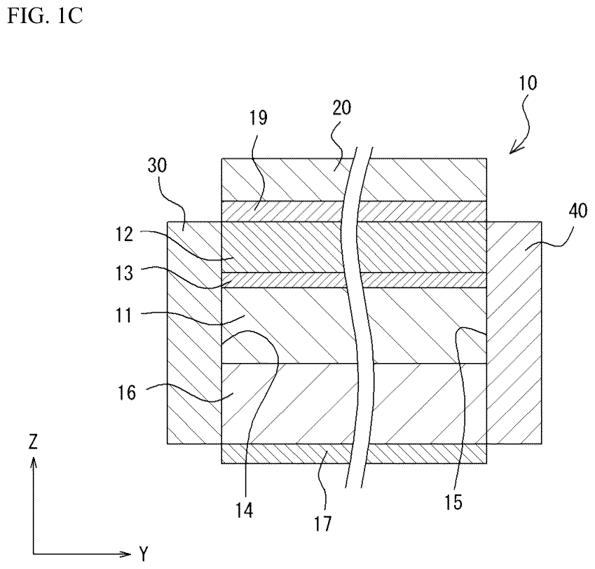

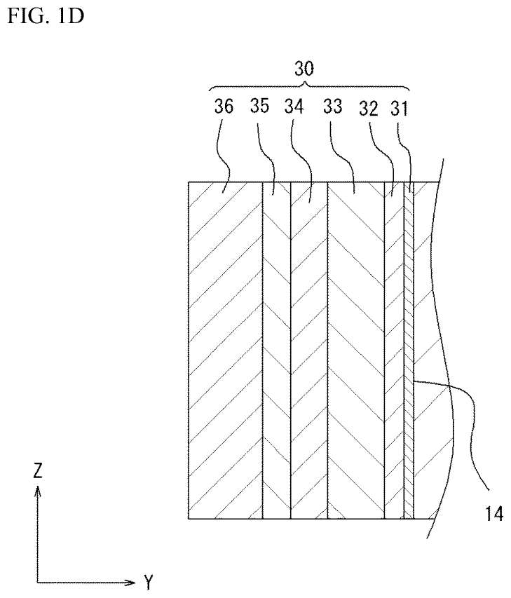

FIGS. 1A to 1D illustrate a nitride semiconductor laser element (hereinafter referred to as a semiconductor laser element in some cases) according to the present embodiment. FIG. 1A is a schematic perspective view of the nitride semiconductor laser element of the present embodiment. FIG. 1B is a schematic front view of FIG. 1A. FIG. 1C is a schematic cross-sectional view taken along a line IC-IC in FIG. 1A. FIG. 1D is a partially enlarged view illustrating an example of a protective film on a side of a light emission side end surface. FIGS. 1A and 1B omit a protective film 30 and a protective film 40.

A nitride semiconductor laser element 10 is an edge-emitting laser element. The nitride semiconductor laser element 10 includes a first nitride semiconductor layer 11, a second nitride semiconductor layer 12, an active layer 13 disposed between the first nitride semiconductor layer 11 and the second nitride semiconductor layer 12, and the protective film 30. The first nitride semiconductor layer 11, the active layer 13, and the second nitride semiconductor layer 12 have a light emission side end surface 14 and a light reflection side end surface 15 as surfaces intersecting with a surface of the active layer 13 on a side of the second nitride semiconductor layer 12. A layered body including the first nitride semiconductor layer 11, the active layer 13, and the second nitride semiconductor layer 12 may be referred to as a nitride semiconductor layered body.

The protective film 30 is provided on the light emission side end surface 14. The protective film 30 includes a first film 31 containing aluminum and/or gallium and oxygen, a second film 32 formed of a nitride film, a first Al-containing film 33 containing aluminum and oxygen, a first silicon oxide film 34, a second Al-containing film 35 containing aluminum and oxygen, and a second silicon oxide film 36 in this order from a side of the light emission side end surface 14. The second silicon oxide film 36 is disposed on the outermost side of the protective film 30.

With such a configuration, the likelihood of generation of catastrophic optical damage of the nitride semiconductor laser element 10 can be reduced. The reason why this effect can be obtained is considered as follows. First, since the first film 31 in the protective film 30 is a film containing oxygen, a resistance is less likely to change during driving, and a decrease in the resistance can be avoided. In addition, since the first Al-containing film 33 is a film containing oxygen, it is possible to reduce a possibility that oxidation of the first Al-containing film 33 proceeds. In addition, since the second film 32, which is a nitride film, is present between the first film 31 and the first Al-containing film 33, it is possible to reduce a possibility that the second film 32 reacts with oxygen in the air or the atmosphere to be oxidized and expanded. Further, by including the first silicon oxide film 34, the second Al-containing film 35, and the second silicon oxide film 36, the number of films constituting the protective film 30 is increased compared with a case in which they are not included. Thus, the plurality of films can suppress local peeling between the films that may occur due to driving of the nitride semiconductor laser element 10, and a possibility of occurrence of the local peeling can be reduced. Since the silicon oxide film is less likely to react with a sealing medium that seals the nitride semiconductor laser element 10 than the Al-containing film, by disposing the second silicon oxide film 36 on the outermost side, it is possible to reduce a possibility that the protective film 30 reacts with the sealing medium (for example, a gas containing oxygen) and is altered. As a result, it is presumable that the likelihood of occurrence of catastrophic optical damage (COD) can be effectively reduced. By reducing the likelihood of occurrence of the catastrophic optical damage, lifetime of the nitride semiconductor laser element 10 can be extended. Such an effect is particularly remarkable in the high-output nitride semiconductor laser element 10.

The high-output nitride semiconductor laser element 10 is, for example, an element having an optical density of 2 MW/cm² or more. The optical density of the nitride semiconductor laser element 10 may be 200 MW/cm² or less. The high-output nitride semiconductor laser element 10 is, for example, an element having an output of 1 W or more or may be an element of 5 W or more when a transverse mode is a multi-mode. The high-output nitride semiconductor laser element 10 is, for example, an element having an output of 0.1 W or more when the transverse mode is a single mode. The output of the nitride semiconductor laser element 10 may be 3 W or less.

### First Nitride Semiconductor Layer 11, Active Layer 13, and Second Nitride Semiconductor Layer 12

The first nitride semiconductor layer 11, the active layer 13, and the second nitride semiconductor layer 12 are layered in this order. The nitride semiconductor layered body including these semiconductor layers can be formed on a substrate 16. The nitride semiconductor layered body has crystallinity.

The first nitride semiconductor layer 11 exhibits a first conductivity type, and the second nitride semiconductor layer 12 exhibits a second conductivity type. The first conductivity type may be either n-type or p-type. The second conductivity type means a conductivity type different from the first conductivity type. The first nitride semiconductor layer 11, the active layer 13, and the second nitride semiconductor layer 12 can be formed using a semiconductor layer made of InₓAl_{y}Ga_{1-x-y}N (0≤x≤1, 0≤y≤1, 0≤x+y≤1). The first nitride semiconductor layer 11 and the second nitride semiconductor layer 12 may contain any one or more of Si, Ge, and the like as an n-type impurity. The first nitride semiconductor layer 11 and the second nitride semiconductor layer 12 may contain any one or more of Mg, Zn, and the like as a p-type impurity. The impurities can each be contained in a range, for example, from 5×10¹⁶/cm³ to 1×10²¹/cm³. The first nitride semiconductor layer 11 and the second nitride semiconductor layer 12 may include an undoped layer. The undoped layer refers to a layer that is intentionally doped with no n-type or p-type impurity. The undoped layer may be a layer having an impurity concentration that does not exceed a detection limit in an analysis result of secondary ion mass spectrometry (SIMS) or the like or having an impurity concentration of less than 1×10¹⁶/cm³. Each of the first nitride semiconductor layer 11 and the second nitride semiconductor layer 12 may include only one semiconductor layer, but preferably includes two or more semiconductor layers.

A semiconductor laser formed using the first nitride semiconductor layer 11, the active layer 13, and the second nitride semiconductor layer 12 has an oscillation peak wavelength in a range from 200 nm to 700 nm.

### First Nitride Semiconductor Layer 11

The first nitride semiconductor layer 11 can have a multilayer structure formed using a nitride semiconductor, such as GaN, InGaN, or AlGaN. In a case in which the first nitride semiconductor layer 11 is formed on the substrate 16, the first nitride semiconductor layer 11 includes, for example, an underlayer, a cladding layer, a crack prevention layer, an intermediate layer, a light guide layer, and the like. The first nitride semiconductor layer 11 may include a semiconductor layer other than these layers.

### Active Layer 13

The active layer 13 may have a quantum well structure. The active layer 13 may have either a multiple quantum well structure or a single quantum well structure.

The active layer 13 can have a multilayer structure formed using a nitride semiconductor, such as GaN or InGaN. When the active layer 13 has the multiple quantum well structure, the active layer 13 includes, for example, a well layer, an intermediate barrier layer, and a well layer in this order from a side of the first nitride semiconductor layer 11. A plurality of the well layers and a plurality of the intermediate barrier layers may be provided. The well layer is, for example, an InGaN layer. The intermediate barrier layer is, for example, an InGaN layer or a GaN layer. The active layer 13 is, for example, an undoped layer.

The composition of the active layer 13 can be appropriately adjusted in accordance with the desired oscillation wavelength of the nitride semiconductor laser element. For example, the well layer can be a layer made of InₓGa₁₋ₓN or the like. An In composition ratio x can be selected from a range from 0.01 to 0.50. As a result, the oscillation peak wavelength of the semiconductor laser can be set in a range from 360 nm to 700 nm. The well layer may be a layer made of GaN or AlGaN.

### Second Nitride Semiconductor Layer 12

The second nitride semiconductor layer 12 can have a multilayer structure formed using a nitride semiconductor, such as GaN, InGaN, or AlGaN. The second nitride semiconductor layer 12 includes, for example, a cladding layer, a light guide layer, and the like. The second nitride semiconductor layer 12 may include a semiconductor layer other than these layers.

As long as the edge-emitting laser element is configured, a surface, that is, an upper surface of the second nitride semiconductor layer 12 may have a ridge 12a, or a current confinement layer known in the field may be disposed in the second nitride semiconductor layer 12. For example, the second nitride semiconductor layer 12 is a p-type semiconductor layer, and the ridge 12a is formed on the upper surface thereof. The second nitride semiconductor layer 12 may be an n-type semiconductor layer.

The ridge 12a functions as an optical wave guide region, and has a width in a range from 1 μm to 30 μm, for example. When the nitride semiconductor laser element 10 is driven at a high output, the ridge 12a can have the width in a range from 1.5 μm to 500 μm. A height of the ridge 12a is in a range from 0.1 μm to 2 μm, for example. A degree of optical confinement can be appropriately adjusted by adjusting a thickness, a material, and the like of the layer included in the second nitride semiconductor layer 12. The ridge 12a can have a length in a resonator direction in a range from 200 μm to 5000 μm. The entire ridge 12a need not have the same width in the resonator direction, and lateral surfaces thereof may be vertical or tapered. In this case, the taper angle is, for example, in a range from 45 degrees to less than 90 degrees.

In each of the first nitride semiconductor layer 11, the active layer 13, and the second nitride semiconductor layer 12, a crystal plane of a layering plane is not particularly limited, and may be any of a C-plane {0001}, an M-plane {1-100}, an A-plane {11-20}, and an R-plane {1-102}, or may be a plane other than these planes. For example, the upper surface of the second nitride semiconductor layer 12 is the C-plane. When a crystal plane and a crystal orientation are represented, while the opposite direction of 1 is represented by a bar above 1 according to the notation of crystallography, it is represented as “−1” for convenience. In addition, an individual orientation is indicated by [ ], a group orientation is indicated by < >, an individual plane is indicated by ( ), and a group plane is indicated by { }.

### Light Emission Side End Surface 14 and Light Reflection Side End Surface 15

The light emission side end surface 14 and the light reflection side end surface 15 are end surfaces of the semiconductor layers including at least a light-emitting surface 14a and a light-reflecting surface on both sides of a region corresponding to the optical wave guide region or a near field pattern (NFP) of the active layer 13. The light emission side end surface 14 and the light reflection side end surface 15 are planes intersecting with a layering plane of the first nitride semiconductor layer 11, the active layer 13, and the second nitride semiconductor layer 12 (an X-Y plane in FIG. 1A). The light emission side end surface 14 and the light reflection side end surface 15 may be inclined with respect to the layering direction of the semiconductor layers (a direction of an arrow Z in FIG. 1A), but are preferably parallel thereto. Further, it is preferable that the light emission side end surface 14 and the light reflection side end surface 15 intersect perpendicularly with the layering plane of the semiconductor layers (the X-Y plane in FIG. 1A). The light emission side end surface 14 and the light reflection side end surface 15 are surfaces opposed to each other, and are preferably disposed parallel to each other. A resonator is formed between the light emission side end surface 14 and the light reflection side end surface 15. The term “parallel” used here allows a difference within ±5 degrees. The term “perpendicular” used here allows a difference within ±5 degrees.

The light emission side end surface 14 and the light reflection side end surface 15 may be any one of the M-plane {1-100}, the A-plane {11-20}, the C-plane {0001}, and the R-plane {1-102}, or may be a plane other than these planes. For example, the light emission side end surface 14 is the M-plane. When the light emission side end surface 14 and the light reflection side end surface 15 are the M-planes, these planes may be obtained by cleavage. The cleavage can be performed by, for example, forming a recessed portion by laser processing and then pressing the recessed portion. A scanning direction of the laser processing may be the same as or different from an advancing direction of the cleavage. The light emission side end surface 14 need not be exactly the M-plane.

### Protective Film 30

The protective film 30 (first protective film) includes the first film 31 containing aluminum and/or gallium and oxygen, the second film 32 formed of a nitride film, the first Al-containing film 33 containing aluminum and oxygen, the first silicon oxide film 34, the second Al-containing film 35 containing aluminum and oxygen, and the second silicon oxide film 36 on the light emission side end surface 14 in this order from the side of the light emission side end surface 14. The protective film 30 may include a film other than these films. The protective film 30 is constituted of, for example, only these films.

The protective film 30 provided on the light emission side end surface 14 covers a resonator surface formed in the semiconductor layer, but does not necessarily cover the entire surface of the light emission side end surface 14. The protective film 30 covers at least the light-emitting surface 14a, which is an end surface of a region corresponding to the optical wave guide region or the NFP of the resonator surface, that is, a region extending from a part of the active layer 13 to parts of upper and lower layers thereof. The protective film 30 may cover the entire surface of the light emission side end surface 14. A part of the protective film 30 may be disposed on a surface other than the resonator surface, for example, on the upper surface or the lateral surface of the semiconductor layer. Each of the films constituting the protective film 30 is formed of a material having light transmissivity for the oscillation wavelength of the nitride semiconductor laser element 10.

### First Film 31

The first film 31 is a film disposed in contact with the light emission side end surface 14. “In contact with” means not only that the first film 31 is in direct contact with the resonator surface, but may mean that the first film 31 is formed on a thin film formed on the resonator surface to such an extent that the effects of the present embodiment are provided. For example, there may be a thin film formed by pretreatment of the resonator surface, an atmosphere at the start of film formation, or the like. The thickness of such a thin film is, for example, less than the thickness of the first film 31. Such a thin film may have a thickness of, for example, 3 nm or less or 1 nm or less. Such a thin film contains, for example, gallium (Ga) and oxygen (O).

The first film 31 may be any one of an oxide film containing aluminum (Al), an oxide film containing Ga, and an oxide film containing Al and Ga. Examples of the oxide film containing Al include a film made of aluminum oxide, such as a film made of Al₂O₃. Examples of the oxide film containing Ga include a film made of gallium oxide, such as a film made of Ga₂O₃. Examples of the oxide film containing Al and Ga include a film made of aluminum gallium oxide, such as a film made of AlGaO. Such a film can suppress a change in the resistance during driving of the semiconductor laser element. When the first film 31 is the oxide film containing Al, it is possible to easily form a film having crystallinity. The first film 31 is a film made of, for example, Al₂O₃. The first film 31 may be an insulating film.

The first film 31 is preferably a crystalline film. When the first film 31 is the crystalline film, it is easy to form the second film 32 as a crystalline film, and an oxidation reaction between the first film 31 and the light emission side end surface 14 is less likely to occur. In a case in which the first film 31 has crystallinity, the first film 31 is a single crystalline film, a polycrystalline film, or a film in which a single crystal and a polycrystal are mixed. The single crystal has little variation in lattice constant in the material and little lattice plane tilt. That is, the atomic arrangement is regular in the material, and a long-range order is maintained. The polycrystal is constituted of a large number of minute single crystals, that is, microcrystals. The crystallinity of such a film can be determined by an electron diffraction image. When an electron beam is incident on the film, an electron diffraction image appears corresponding to a magnitude of the lattice constant and the plane direction. For example, in the case of the single crystal, diffraction spots that are regularly arranged are observed. In the case of the polycrystal, since it is constituted of the microcrystals, orientations of the respective lattice planes are not uniform, and diffraction spots are observed in a state of being complicatedly combined, or Debye rings are observed. On the other hand, in the case of amorphous, since atomic arrangement does not have a long-range periodic structure, electron diffraction does not occur. Therefore, a diffraction image without diffraction spots is observed. The electron diffraction image can be observed by cutting the film, with respect to an end surface on which the film is formed, such that the cross section of the film is exposed, and irradiating the film with an electron beam. The difference in crystallinity can also be confirmed by, for example, cross-sectional observation with a transmission electron microscope (TEM), a scanning transmission electron microscope (STEM), a scanning electron microscope (SEM), or the like, or a difference in an etching rate of etching with an appropriate etchant, such as an acid or an alkali solution. The atomic arrangement may be confirmed by images by high-resolution transmission electron microscopy (HRTEM).

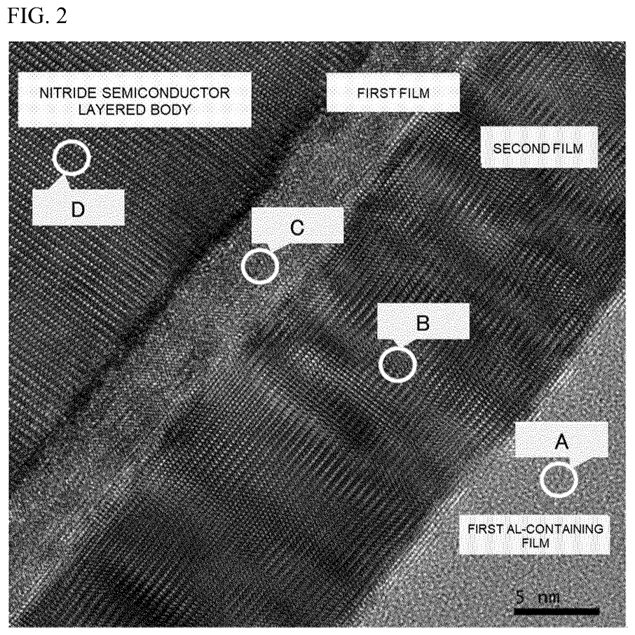

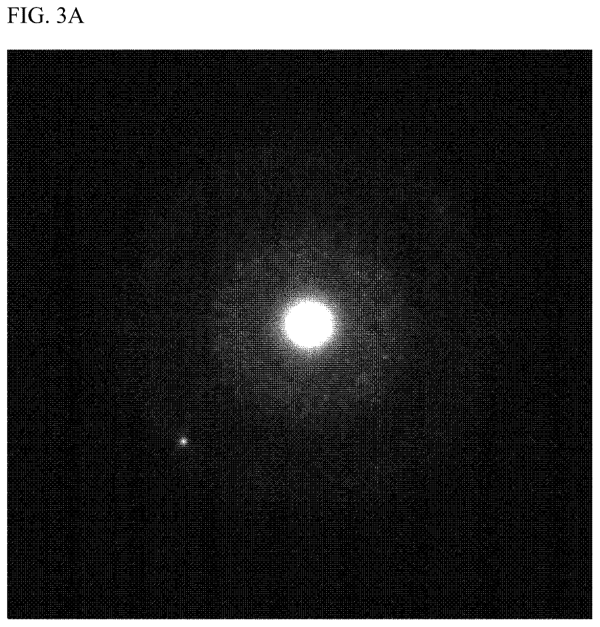

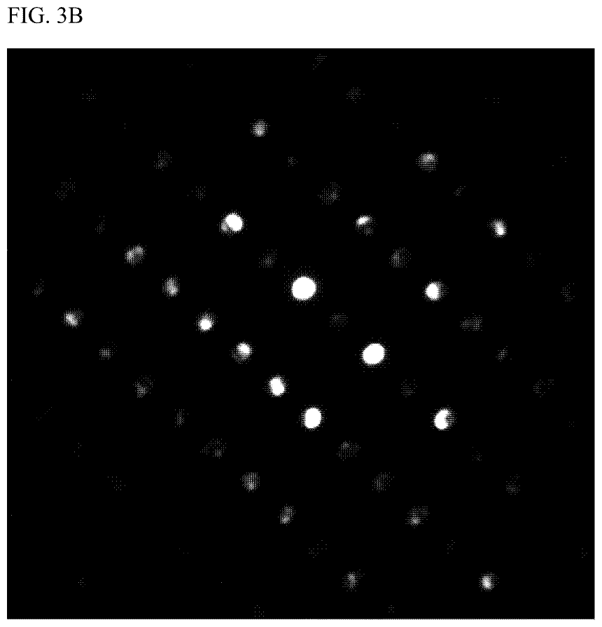

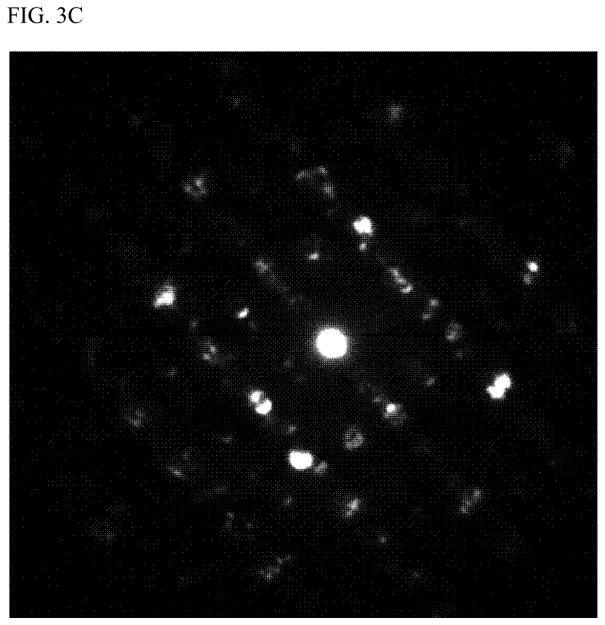

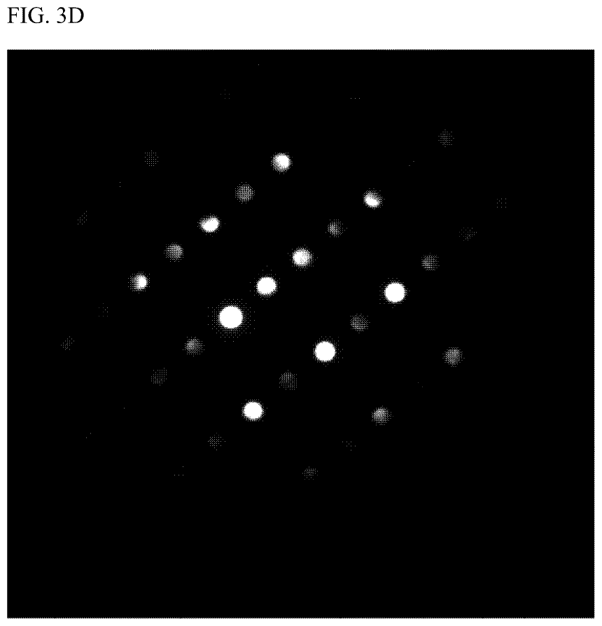

FIG. 2 illustrates an example of a high-resolution transmission electron microscope image of the protective film 30 and its vicinity. The lower right line in FIG. 2 is a line indicating 5 nm. A nitride semiconductor layered body illustrated in FIG. 2 includes the active layer 13. FIG. 3A is an electron diffraction image in a circle indicated by A in FIG. 2 and is an electron diffraction image of the first Al-containing film 33. FIG. 3B is an electron diffraction image in a circle indicated by B in FIG. 2 and is an electron diffraction image of the second film 32. FIG. 3C is an electron diffraction image in a circle indicated by C in FIG. 2 and is an electron diffraction image of the first film 31. FIG. 3D is an electron diffraction image in a circle indicated by D in FIG. 2 and is an electron diffraction image of the nitride semiconductor layered body. From FIG. 3C, it was confirmed that the first film 31 was crystalline, that is, the first film 31 was a film having crystallinity. From FIG. 3D, it was confirmed that the nitride semiconductor layered body was crystalline, that is, the nitride semiconductor layered body had crystallinity.

Examples of the crystal structure of the first film 31 include a cubic crystal structure, a tetragonal crystal structure, and a hexagonal crystal structure. The material, the crystallinity, the orientation, and the like of the first film 31 can be selected according to the material, the crystallinity, the orientation, and the like of the light emission side end surface 14 on which the first film 31 is formed. Examples of the film having crystallinity include a film partially including a single crystal and/or a polycrystal or a film including only a single crystal and/or a polycrystal. That is, the first film 31 is not necessarily an exact single crystal or an exact polycrystal, and may have a crystal structure close to the single crystal or the polycrystal or a crystal structure exhibiting characteristics of any of these crystal structures. In the first film 31, the crystallinity may be different between the region corresponding to the optical wave guide region or the NFP, the lateral surface side of the active layer 13, and the side far from the active layer 13 in the thickness direction of the first nitride semiconductor layer 11 and the second nitride semiconductor layer 12. The first film 31 is preferably crystalline in substantially the entire region in the thickness direction in the region corresponding to the optical wave guide region or the NFP. “Substantially the entire region in the thickness direction” refers to the entire remaining region except a region where it is difficult to distinguish a boundary between adjacent films or the like. For example, the first film 31 is a film at least partially containing a polycrystal. The first film 31 may be a film in which the half or more of a region adjacent to the active layer 13 is constituted of a polycrystal in observation of a cross section cut in a direction intersecting with a primary surface of the active layer 13 and intersecting with the light emission side end surface 14 (for example, the direction perpendicularly intersecting with each of them).

A thickness of the first film 31 is in a range from 1 nm to 100 nm, preferably in a range from 1 nm to 50 nm, and more preferably in a range from 1 nm to 10 nm. The smaller the thickness of the first film 31 is, the easier it tends to be to form the first film 31 as a film having good crystallinity. The thickness of the first film 31 can be in a range from 5 nm to 6 nm or may be 8 nm or more. When the first film 31 has a thickness of 5 nm or more, the lifetime of the nitride semiconductor laser element 10 can be further extended. This is considered to be because the crystallinity of the second film 32 is improved. The first film 31 may have a thickness of 50 nm or less, 20 nm or less, 10 nm or less, or less than 10 nm. For example, the thickness of the first film 31 can be in a range from 5 nm to 10 nm. The first film 31 may have a thickness of less than 10 nm, or a thickness in a range from 5 nm to less than 10 nm. The thickness of the first film 31 refers to a length in a direction parallel to the primary surface of the active layer 13. Similarly, the thicknesses of the second film 32 and the first Al-containing film 33 refer to the lengths in the direction parallel to the primary surface of the active layer 13.

The first film 31 can be formed by a method known in the field. For example, a pulse sputtering method, an electron cyclotron resonance (ECR) sputtering method, a magnetron sputtering method, an ion beam assisted deposition method, a laser ablation method, a chemical vapor deposition (CVD) method, or a method of combination of two or more kinds of these methods can be used. Alternatively, these methods may be combined with the whole or partial pretreatment. As the pretreatment, for example, any one or more kinds of irradiation with an inert gas (Ar, He, Xe, or the like) or plasma, irradiation with oxygen or an ozone gas, oxidation treatment (heat treatment), and exposure treatment can be used.

In particular, the first film 31 is preferably formed by a pulse sputtering method or an ECR sputtering method. For example, the first film 31 can be formed using an ECR sputtering apparatus. Thus, the first film 31 can be obtained as a film having good crystallinity. When the first film 31 is formed using the ECR sputtering apparatus, a flow rate of oxygen during the formation is preferably 1.33×10⁻⁷ m³/s or more. Pretreatment may be performed before the first film 31 is formed. Examples of the pretreatment include treatment of the light emission side end surface 14 with oxygen plasma. Examples of the pulse sputtering method include a method in which an oxide target is used and a method in which sputtering is intermittently performed using a non-oxide target in an oxygen atmosphere or while irradiation with an oxygen gas, plasma, or the like is performed. There is a tendency that the temperature during the film formation in the ECR sputtering method can be lower than that in the pulse sputtering method. As a result, deterioration of characteristics of electrodes described later can be suppressed.

As described above, by forming the first film 31, as a film containing oxygen, in contact with the light emission side end surface 14, a change in the resistance can be suppressed when the nitride semiconductor laser element 10 is driven. In addition, by forming the first film 31 as a crystalline film, it is easy to form the second film 32 as a crystalline film. It is presumable that when the thickness of the first film 31 is relatively small, for example, thinner than the first Al-containing film 33, stress caused by heat due to driving can be relaxed at the light emission side end surface 14 during driving of the nitride semiconductor laser element 10. In addition, the adhesion between the light emission side end surface 14 and the protective film 30 can be improved.

### Second Film 32

The second film 32 is a film disposed in contact with the first film 31. The second film 32 is a nitride film. Examples of the nitride film specifically include a film made of AlN, GaN, AlGaN, or the like. Among them, an AlN film is preferable. Since the AlN film can be formed by the ECR sputtering method, for example, both the first film 31 and the second film 32 can be formed using the ECR sputtering apparatus. The first film 31 and the second film 32 may be continuously grown.

The second film 32 is preferably a film having crystallinity. Thus, the action of the second film 32 as an oxygen barrier film can be effectively achieved. This makes it possible to reduce the possibility that the light emission side end surface 14 is oxidized by oxygen from the first Al-containing film 33 or outside the nitride semiconductor laser element 10. The orientation of the second film 32 in the thickness direction may be any of orientations of the M-axis <1-100>, the A-axis <11-20>, the C-axis <0001>, and the R-axis <1-102>, or may be an orientation other than them. For example, the second film 32 is C-axis oriented with respect to the M-axis of the nitride semiconductor layered body. In this case, the M-axis of the nitride semiconductor layered body is parallel to the C-axis of the second film 32. The crystal axis orientation in the region of the second film 32 adjacent to the active layer 13 may be the same as the crystal axis orientation in the region of the second film 32 adjacent to the first nitride semiconductor layer 11 and/or the region adjacent to the second nitride semiconductor layer 12. In that case, it is easy to form the second film 32 with good crystallinity. For example, in the second film 32, the region adjacent to the active layer 13 and the region adjacent to the first nitride semiconductor layer 11 and/or the second nitride semiconductor layer 12 are both C-axis oriented. For example, the C-axis of the region of the second film 32 adjacent to the active layer 13 is parallel to the C-axis of the region of the second film 32 adjacent to the first nitride semiconductor layer 11 and/or the second nitride semiconductor layer 12. The region of the second film 32 adjacent to a specific layer (for example, the active layer 13) refers to a region of the second film 32 interposed between an extension plane (imaginary plane) obtained by extending one primary surface of the layer and an extension plane (imaginary plane) obtained by extending the other primary surface. The second film 32 may have the same crystal axis orientation throughout the second film 32. The crystallinity of each region of the second film 32 can be evaluated using a cross section cut in a direction intersecting with the primary surface of the active layer 13 (for example, a perpendicular direction).

The thickness of the second film 32 is, for example, in a range from 5 nm to 500 nm, may be in a range from 5 nm to 200 nm, may be in a range from 5 nm to 100 nm, or may be in a range from 5 nm to 50 nm. By setting the thickness of the second film 32 in such a range, the film having good crystallinity can be obtained, and the action thereof as the oxygen barrier film can be effectively achieved. It is presumable that generation of cracks is easily suppressed when the second film 32 has a thickness of 50 nm or less. To adjust a reflectance of the protective film 30, the second film 32 may have a thickness larger than 50 nm. The thickness of the second film 32 may be 20 nm or more and may be 40 nm or more. This makes it possible to further extend the lifetime. The thicknesses of the second films 32 may be in a range from 20 nm to 100 nm, may be in a range from 40 nm to 100 nm, or may be in a range from 40 nm to 50 nm. This makes it possible to further extend the lifetime of the nitride semiconductor laser element 10.

The second film 32 can be formed by a known method, such as a sputtering method or the ECR sputtering method. Examples of the sputtering method include a method in which a nitride target is used and a method in which sputtering is performed using a non-nitride target in a nitrogen atmosphere or while irradiation with a nitrogen gas, plasma, or the like is performed.

Regarding the example of the second film 32 illustrated in FIG. 2, from FIG. 3B, it was confirmed that the second film 32 was crystalline, that is, the second film 32 was a film having crystallinity.

### First Al-Containing Film 33

The first Al-containing film 33 can be disposed in contact with the second film 32. The first Al-containing film 33 is a film containing Al and O. The first Al-containing film 33 may be an oxide film containing Al or an oxynitride film containing Al. The first Al-containing film 33 may be a film made of aluminum oxide. When the first Al-containing film 33 is such a film, it is possible to reduce the possibility that the first Al-containing film 33 is oxidized. Therefore, a possibility that oxygen reaches the nitride semiconductor layered body can be reduced. It is presumable that oxidation of the first Al-containing film 33 is less likely to progress in the oxide film containing Al than in the oxynitride film containing Al when the nitride semiconductor laser element 10 is driven. As a result, the lifetime of the nitride semiconductor laser element 10 can be further extended. The first Al-containing film 33 is a film made of, for example, Al₂O₃.

The first Al-containing film 33 may be a film having crystallinity or may be a film including an amorphous structure. The amorphous structure means a structure that does not have a periodic structure, such as atomic arrangement, in a crystal, that is, a structure in which atomic arrangement is irregular and has no long-range order. The first Al-containing film 33 is preferably a film having an amorphous structure or a film including an amorphous structure and a crystal structure, and among them, the film having only the amorphous structure is preferable. In that case, it is easy to make the thickness of the first Al-containing film 33 larger than the thickness of the first film 31 and/or the second film 32. When the first Al-containing film 33 includes the amorphous structure, a part of the first Al-containing film 33, for example, a part on the active layer 13 side, may become a film having crystallinity by driving of the nitride semiconductor laser element 10. In that case, it is presumable that the lifetime of the nitride semiconductor laser element 10 can be further extended. For example, in a case in which the first Al-containing film 33 is a film made of Al₂O₃, such crystallization may occur.

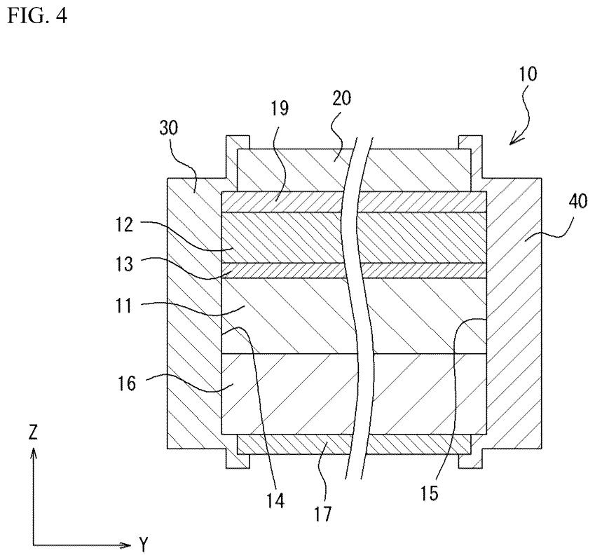

The thickness of the first Al-containing film 33 is preferably larger than the thickness of the first film 31. The thickness of the first Al-containing film 33 may be smaller than the thickness of the second film 32, but is preferably larger than the thickness of the second film 32. Thus, the total thickness of the protective film 30 can be increased. The thickness of the first Al-containing film 33 is, for example, equal to or larger than three times the thickness of the first film 31 or may be equal to or larger than ten times the thickness of the first film 31. The thickness of the first Al-containing film 33 is preferably in a range from 10 nm to 1000 nm, and more preferably in a range from 50 nm to 500 nm. By setting the thickness of the first Al-containing film 33 in such a range, the total thickness of the protective film 30 can be increased. Therefore, a possibility that oxygen from outside the nitride semiconductor laser element 10 passes through the protective film 30 and reaches the nitride semiconductor layered body can be reduced. It is presumable that this can advantageously act on the extension of the lifetime. In particular, when the first film 31 and the second film 32 are formed as films thinner than the first Al-containing film 33 to achieve their functions, a more remarkable effect can be obtained. In addition, when the first Al-containing film 33 includes an amorphous structure, the crystallization by driving is less likely to be caused with a too thin thickness of the first Al-containing film 33. Therefore, from this aspect as well, the first Al-containing film 33 preferably has a thickness in the above-described range. From this aspect, it is preferable that the thickness of the first Al-containing film 33 is larger than the thickness of the second Al-containing film 35. The first Al-containing film 33 may have a thickness in a range of ±25% of (λ/2n₃)×2. λ is the oscillation wavelength of the nitride semiconductor laser element 10, and n₃ is a refractive index of the first Al-containing film 33 at the oscillation wavelength λ. As a result, the lifetime of the nitride semiconductor laser element 10 can be extended compared with a case in which the thickness of the first Al-containing film 33 is smaller than the thickness in the above range. This is presumably because, by increasing the thickness of the protective film 30, it is possible to lengthen time until breakage proceeding from the inside of the nitride semiconductor laser element 10 reaches an outer surface of the protective film 30. As illustrated in FIG. 4, a part of the protective film 30 may be provided on the upper surface side and/or the lower surface side of the nitride semiconductor layered body. FIG. 4 is a cross-sectional view illustrating another example of the nitride semiconductor laser element 10. By providing the protective film 30 in this manner, it is presumable that a distance until the breakage reaches the outer surface of the nitride semiconductor laser element 10 can be lengthened by the thickness of the protective film 30 on the upper surface side and/or the lower surface side of the nitride semiconductor layered body. Therefore, the lifetime of the nitride semiconductor laser element 10 can be extended.

The first Al-containing film 33 can be formed by a known method, such as the sputtering method or the ECR sputtering method. For example, the first Al-containing film 33 can be formed using the ECR sputtering apparatus. When the first film 31 and the first Al-containing film 33 are formed using the ECR sputtering apparatus, the flow rate of oxygen at the time of forming the first Al-containing film 33 is lower than the flow rate of oxygen at the time of forming the first film 31. Thus, the first film 31 can be formed as a crystalline film, and the first Al-containing film 33 can be formed as a film having an amorphous structure.

Regarding the example of the first Al-containing film 33 illustrated in FIG. 2, it was confirmed from FIG. 3A that the first Al-containing film 33 was amorphous, that is, the first Al-containing film 33 was a film having an amorphous structure.

### First Silicon Oxide Film 34

The first silicon oxide film 34 is provided on a side of the first Al-containing film 33 opposite to the second film 32. The first silicon oxide film 34 can be disposed in contact with the first Al-containing film 33. By providing the first silicon oxide film 34, it is possible to lengthen the distance until the breakage proceeding from the inside of the nitride semiconductor laser element 10 reaches the outer surface of the protective film 30 compared with a case in which the first silicon oxide film 34 is not provided.

For example, a refractive index n₄ of the first silicon oxide film 34 at the oscillation wavelength λ is smaller than a refractive index n₃ of the first Al-containing film 33 at the oscillation wavelength λ. Examples of the first silicon oxide film 34 include a film made of silicon oxide (for example, SiO₂). Thus, there is an advantage that deterioration of initial characteristics and heat generation due to light absorption can be suppressed.

The thickness of the first silicon oxide film 34 may be smaller than the thickness of the first Al-containing film 33. For example, the thickness of the first silicon oxide film 34 can be set to a thickness in a range of ±5% of λ/4n₄.

The first silicon oxide film 34 is preferably a film including an amorphous structure. This makes it possible to improve the adhesion with the first Al-containing film 33. In addition, it is presumable that, when the first Al-containing film 33 is a film including an amorphous structure and is crystallized by driving, excessive or insufficient oxygen can be adjusted by the first silicon oxide film 34. That is, it is presumable that excessive oxygen for crystallization of the first Al-containing film 33 can be released to the first silicon oxide film 34, and insufficient oxygen for crystallization of the first Al-containing film 33 can be supplied from the first silicon oxide film 34.

The first silicon oxide film 34 can be formed by a known method, such as the sputtering method or the ECR sputtering method.

### Second Al-Containing Film 35

The second Al-containing film 35 is provided on a side of the first silicon oxide film 34 opposite to the first Al-containing film 33. The second Al-containing film 35 can be disposed in contact with the first silicon oxide film 34. By providing the second Al-containing film 35, it is possible to lengthen the distance until the breakage proceeding from the inside of the nitride semiconductor laser element 10 reaches the outer surface of the protective film 30 compared with a case in which the second Al-containing film 35 is not provided.

The second Al-containing film 35 may be made of the same material as the first Al-containing film 33. The second Al-containing film 35 is a film made of, for example, Al₂O₃. The second Al-containing film 35 is preferably a film including an amorphous structure. This makes it possible to improve the adhesion with the first silicon oxide film 34. When the first Al-containing film 33 is crystallized by driving of the nitride semiconductor laser element 10, the second Al-containing film 35 need not be crystallized by driving of the nitride semiconductor laser element 10.

The reflectance of the protective film 30 can be adjusted by the thicknesses of the second Al-containing films 35. For example, the thickness of the second Al-containing film 35 is smaller than the thickness of the first Al-containing film 33. The thickness of the second Al-containing film 35 can be set to a thickness in a range of ±5% of λ/4n₅. n₅ is a refractive index of the second Al-containing film 35 at the oscillation wavelength λ.

The second Al-containing film 35 can be formed by a known method, such as the sputtering method or the ECR sputtering method. For example, the second Al-containing film 35 can be formed using the ECR sputtering apparatus.

### Second Silicon Oxide Film 36

The second silicon oxide film 36 is provided on a side of the second Al-containing film 35 opposite to the first silicon oxide film 34. The second silicon oxide film 36 can be disposed in contact with the second Al-containing film 35. By providing the second silicon oxide film 36, it is possible to lengthen the distance until the breakage proceeding from the inside of the nitride semiconductor laser element 10 reaches the outer surface of the protective film 30 compared with a case in which the second silicon oxide film 36 is not provided. Blowing away of the protective film 30 is one of the causes of sudden death of the nitride semiconductor laser element 10. However, by providing the second silicon oxide film 36, the thickness of the entire protective film 30 can be increased compared with a case in which the second silicon oxide film 36 is not provided, and thus there is a possibility that the sudden death of the nitride semiconductor laser element 10 can be suppressed.

The second silicon oxide film 36 is disposed on the outermost side of the protective film 30. The second silicon oxide film 36 has a first surface, which is a surface on the side of the light emission side end surface 14, and a second surface, which is a surface located on the side opposite to the first surface. The second surface of the second silicon oxide film 36 is in contact with a sealing medium that seals the nitride semiconductor laser element 10. The sealing medium is, for example, a gas containing oxygen. The first surface of the second silicon oxide film 36 is, for example, a surface in contact with the second Al-containing film 35.

As illustrated in FIG. 4, when a part of the protective film 30 is provided on the upper surface side and/or the lower surface side of the nitride semiconductor layered body, the films constituting the protective film 30 other than the second silicon oxide film 36 can be covered with the second silicon oxide film 36. Thus, the possibility of deterioration of the protective film 30 by driving of the nitride semiconductor laser element 10 can be further reduced. Only the second silicon oxide film 36 may be in contact with the sealing medium sealing the nitride semiconductor laser element 10, among the films constituting the protective film 30.

The second silicon oxide film 36 may be made of the same material as the first silicon oxide film 34. The second silicon oxide film 36 is a film made of, for example, SiO₂. The second silicon oxide film 36 is preferably a film including an amorphous structure. This makes it possible to improve the adhesion with the second Al-containing film 35.

The thickness of the second silicon oxide film 36 can be larger than the thickness of the first silicon oxide film 34. As a result, protection performance by the second silicon oxide film 36 can be further improved. The thickness of the second silicon oxide film 36 may be larger than the thickness of the first Al-containing film 33. For example, the thickness of the second silicon oxide film 36 can be set to a thickness in a range of ±5% of λ/2n₆. n₆ is a refractive index of the second silicon oxide film 36 at the oscillation wavelength λ.

The second silicon oxide film 36 can be formed by a known method, such as the sputtering method or the ECR sputtering method.

With such a configuration, the nitride semiconductor laser element 10 of the present embodiment can reduce the probability of occurrence of catastrophic optical damage and achieve the extension of lifetime.

### Protective Film 40

The protective film 40 (second protective film) is provided on the light reflection side end surface 15. The protective film 40 has a film structure different from or the same as that of the protective film 30 on the side of the light emission side end surface 14. The reflectance of the protective film 40 with respect to the oscillation wavelength of the nitride semiconductor laser element 10 is higher than the reflectance of the protective film 30 with respect to the oscillation wavelength of the nitride semiconductor laser element 10.

The protective film 40 on the side of the light reflection side end surface 15 may include the same film as the multilayer film of the first film 31, the second film 32, and the first Al-containing film 33 described above. The protective film 40 may be a film made of an oxide of Si, Mg, Al, Hf, Nb, Zr, Sc, Ta, Ga, Zn, Y, B, Ti, or the like (particularly, Al₂O₃, SiO₂, Nb₂O₅, TiO₂, ZrO₂, or the like), a nitride thereof (particularly, AlN, AlGaN, BN, or the like), a fluoride thereof, a combination of two or more kinds of the oxide, the nitride, and the fluoride, or the like. When the same film as the multilayer film of the first film 31, the second film 32, and the first Al-containing film 33 is formed, the film may be formed to a different thickness or the like from that of the protective film 30 on the side of the light emission side end surface 14. The protective film 40 is preferably formed of a material that is light-transmissive and/or reflective with respect to the oscillation wavelength of the nitride semiconductor laser element 10. The protective film 40 may be a single layer or a multilayer.

Examples of the protective film 40 on the light reflection side end surface 15 include a layered film of an oxide of Si and an oxide of Zr, a layered film of an oxide of Al and an oxide of Zr, a layered film of an oxide of Si and an oxide of Ti, a layered film of an oxide of Al, an oxide of Si, and an oxide of Zr, and a layered film of an oxide of Si, an oxide of Ta, and an oxide of Al. The layering period or the like can be appropriately adjusted in accordance with a desired reflectance.

The thickness of the protective film 40 is not particularly limited, and examples thereof include a range from 100 nm to 4000 nm, a range from 300 nm to 3000 nm, and a range from 500 nm to 2000 nm. For example, the thickness of the protective film 40 is larger than the thickness of the protective film 30.

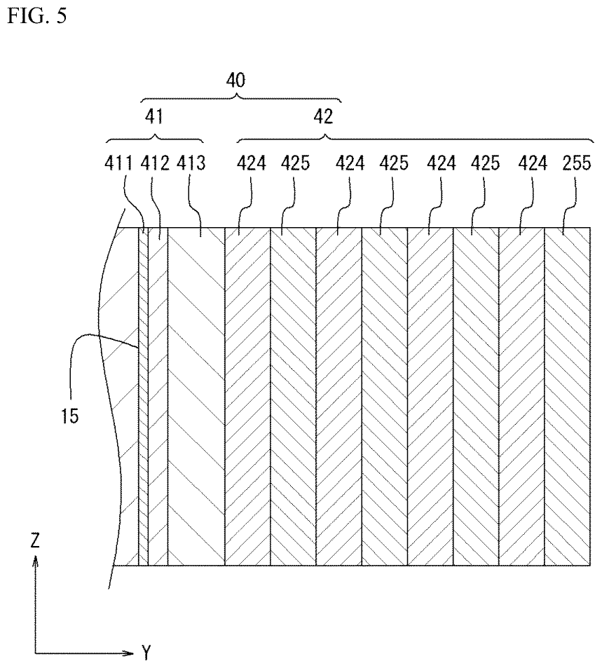

The protective film 40 is, for example, a multilayer film. The multilayer film can have a structure in which a film having a relatively low refractive index and a film having a relatively high refractive index are alternately layered. The film of the multilayer film in contact with the light reflection side end surface 15 may be either a film having a relatively low refractive index or a film having a relatively high refractive index. As illustrated in FIG. 5, the protective film 40 can include a first portion 41 disposed in contact with the light reflection side end surface 15 and a second portion 42 disposed in contact with the first portion 41. FIG. 5 is a partially enlarged view illustrating an example of the protective film 40 on the side of the light reflection side end surface 15. The protective film 40 preferably has a thickness of ±5% of an odd multiple of λ/4n, and further preferably an odd multiple of λ/4n. This makes it possible to reduce the probability of occurrence of optical damage at the light reflection side end surface 15 when the nitride semiconductor laser element 10 is driven. Note that λ is the oscillation wavelength of the nitride semiconductor laser element 10, and n is the refractive index of each film at the oscillation wavelength λ. The thickness of the protective film 40 refers to the length in the direction parallel to the primary surface of the active layer 13. The second portion 42 is formed by alternately disposing high refractive index films 424 and low refractive index films 425. The first portion 41 is formed of one or more films. The film in contact with the second portion 42 in the first portion 41 has a refractive index different from the refractive index of the high refractive index film 424 and the refractive index of the low refractive index film 425. By combining the first portion 41 and the second portion 42, light can be reflected at an interface between the first portion 41 and the second portion 42, and the reflectance of the protective film 40 can be improved. This allows improving the optical output of the nitride semiconductor laser element 10. A distance from the light reflection side end surface 15 to the interface between the first portion 41 and the second portion 42 is preferably in a range from 50 nm to 200 nm. In that case, the reflectance of the protective film 40 can be further improved, and the optical output of the nitride semiconductor laser element 10 can be further improved. Note that the distance refers to the shortest distance. The protective film 40 may include only the first portion 41 and the second portion 42, or may further include another film.

The first portion 41 preferably has a multilayer structure including a film having a relatively low refractive index and a film having a relatively high refractive index. As a result, the reflectance of the protective film 40 can be further improved. For example, the film having a relatively low refractive index in the first portion 41 and the high refractive index film 424 of the second portion 42 are in contact with each other. Alternatively, the film having a relatively high refractive index in the first portion 41 and the low refractive index film 425 of the second portion 42 may be in contact with each other. The film in contact with the first portion 41 in the second portion 42 is preferably a film having a refractive index higher than the refractive index of the film in contact with the second portion 42 in the first portion 41, and more preferably a film having a refractive index higher than the refractive index of any of the films constituting the first portion 41. As a result, the reflectance of the protective film 40 can be further improved. The low refractive index film 425 of the second portion 42 can be, for example, a silicon oxide film (for example, a SiO₂ film). The high refractive index film 424 of the second portion 42 can be, for example, a tantalum oxide film (for example, Ta₂O₅).

The first portion 41 may include a first film 411, a second film 412, and a third film 413. The first portion 41 may include the first film 411 having crystallinity and containing aluminum and/or gallium and oxygen, the second film 412 having crystallinity and formed of a nitride film, and the third film 413 containing aluminum and oxygen, in this order from the side of the light reflection side end surface 15. The material, the thickness, the formation method, and the like described for the first film 31 can be employed for the first film 411. The material, the thickness, the formation method, and the like described for the second film 32 can be employed for the second film 412. The material, the thickness, the formation method, and the like described for the first Al-containing film 33 can be employed for the third film 413. Since the first portion 41 is a portion in contact with the light reflection side end surface 15, an effect similar to that of the protective film 30 can be expected by including the first film 411, the second film 412, and the third film 413 as described above. The first film 411 may be disposed in contact with the light reflection side end surface 15. The respective thicknesses of the first film 411, the second film 412, and the third film 413 may be λ/4n or less. In that case, the interface between the first portion 41 and the second portion 42 can be disposed relatively close to the light reflection side end surface 15, the reflectance of the protective film 40 can be further improved, and the optical output of the nitride semiconductor laser element 10 can be further improved. For example, the first portion 41 is formed of only the first film 411, the second film 412, and the third film 413.

### Substrate 16

The substrate 16 may be an insulating substrate, or may be a conductive substrate. For example, a nitride semiconductor substrate made of GaN or the like can be used as the substrate 16. A first primary surface of the substrate 16, which is a semiconductor layer formation surface, may be the C-plane, the R-plane, the M-plane, or the like, and is, for example, the C-plane. The first primary surface and/or a second primary surface opposite to the first primary surface may have an off angle in a range from 0° to 10°. The substrate 16 has a thickness in a range from 10 μm to 10 mm.

### Buried Film 18, First Electrode 17, Second Electrode 19, Pad Electrode 20

In the nitride semiconductor laser element 10, the buried film 18 can be provided on the upper surface of the second nitride semiconductor layer 12, for example, on the lateral surface of the ridge 12a and on the upper surface of the second nitride semiconductor layer 12 continuous from the lateral surface of the ridge 12a.

The buried film 18 is preferably formed of a material having a refractive index smaller than that of the second nitride semiconductor layer 12. Examples of the buried film 18 include a single-layer film or a multilayer film of an insulating film made of an oxide, a nitride, an oxynitride, or the like of any of Zr, Si, V, Hf, Ta, Al, Ce, In, Sb, Zn, and the like. The buried film 18 can be formed by a method known in the field exemplified as the method of forming the first film 31.

The first electrode 17 can be provided on the lower surface of the first nitride semiconductor layer 11, for example, on the lower surface of the substrate 16 when the substrate 16 is provided. When the substrate 16 is a semiconductor substrate, the substrate 16 has the same conductivity type as that of the first nitride semiconductor layer 11. The first electrode 17 is provided on, for example, substantially the entire lower surface of the substrate 16.

The second electrode 19 can be provided on the upper surface of the second nitride semiconductor layer 12, for example, the upper surface of the ridge 12a, and the pad electrode 20 can be further provided thereon.

The first electrode 17 and the second electrode 19 can be formed of a single-layer film or a multilayer film of a metal, such as Ni, Rh, Cr, Au, W, Pt, Ti, Al, and Pd or an alloy thereof, a conductive oxide containing at least one kind of a metal selected from Zn, In, and Sn, or the like. Examples of the conductive oxide include indium tin oxide (ITO), indium zinc oxide (IZO), and gallium-doped zinc oxide (GZO). The thicknesses of the electrodes each generally only need to be a thickness such that the electrode can function as an electrode of the semiconductor laser element. For example, they are each in a range from 0.1 μm to 2 μm.

The first electrode 17 and the second electrode 19 may be provided on the first primary surface side and the second primary surface side of the nitride semiconductor layered body, respectively, or both of the first electrode 17 and the second electrode 19 may be provided on either one of the first primary surface side and the second primary surface side.

The buried film 18, the first electrode 17, the second electrode 19, and the pad electrode 20 may be separated from or in contact with the protective film 30 described above. The buried film 18, the first electrode 17, the second electrode 19, and the pad electrode 20 may cover the protective film 30 or may be covered with the protective film 30. The buried film 18 and the second electrode 19 are preferably covered with the protective film 30. In that case, it is possible to suppress peeling of the buried film 18 and the second electrode 19.

### EXAMPLES

As the nitride semiconductor laser element 10 illustrated in FIGS. 1A to 1D, a gallium nitride-based semiconductor laser element having a peak of an oscillation wavelength of about 445 nm was produced.

An MOCVD apparatus was used to produce an epitaxial wafer to be the nitride semiconductor laser element 10. As a raw material, trimethylgallium (TMG), triethylgallium (TEG), trimethylaluminum (TMA), trimethylindium (TMI), ammonia (NH₃), a silane gas, or bis(cyclopentadienyl)magnesium (Cp₂Mg) was used as appropriate. An n-side semiconductor layer as the first nitride semiconductor layer 11, the active layer 13, and a p-side semiconductor layer as the second nitride semiconductor layer 12 were grown on an n-type GaN substrate (substrate 16) having a C-plane as a growth plane, and the stripe-shaped ridge 12a having a length of 1200 μm in a direction parallel to a resonator length was formed on a surface of the p-side semiconductor layer.

Subsequently, a p-electrode made of ITO (200 nm) was formed as the second electrode 19 on the surface on the p-side semiconductor layer, and the buried film 18 made of SiO₂ was formed on the lateral surface of the ridge 12a and the upper surface of the p-side semiconductor layer on an outer side of the ridge 12a. The buried film 18 was formed such that a part thereof partially covered the p-electrode.

On the p-electrode, the pad electrode 20 of Ni (8 nm)/Pd (200 nm)/Au (400 nm)/Pt (200 nm)/Au (700 nm) was formed so as to be continuous therewith.

Thereafter, the substrate 16 was polished from the surface opposite to the growth surface of the first nitride semiconductor layer 11 so as to have a thickness of 80 μm, and an n-electrode made of Ti (8 nm)/Pt (100 nm)/Au (300 nm) was formed on the polished surface, as the first electrode 17. Subsequently, the substrate 16 was cleaved in a bar shape from the n-electrode formation surface side, and the cleavage planes were used as resonator surfaces, that is, the light emission side end surface 14 and the light reflection side end surface 15. The light emission side end surface 14 and the light reflection side end surface 15 of the obtained bar were subjected to surface treatment by exposing them to oxygen plasma using the ECR sputtering apparatus. At this time, for example, the flow rate of O₂ was set to 3.33×10⁻⁷ m³/s, and the treatment was performed for 10 minutes in a microwave at 500 W. Thereafter, the first film 31 made of Al₂O₃ was formed, on the light emission side end surface 14, using an Al target at a flow rate of Ar of 5×10⁻⁷ m³/s and a flow rate of oxygen of 1.67×10⁻⁷ m³/s in a microwave at 500W. The oxygen gas was changed to a nitrogen gas and similarly the second film 32 made of AlN was formed. Subsequently, the nitrogen gas was changed to the oxygen gas, and similarly the first Al-containing film 33 made of Al₂O₃ was formed. Subsequently, the first silicon oxide film 34 made of SiO₂, the second Al-containing film 35 made of Al₂O₃, and the second silicon oxide film 36 made of SiO₂ were formed. As a result, the protective film 30 was formed.

The flow rate of oxygen during the formation of the first film 31 was 1.67×10⁻⁷ m³/s, and the flow rate of oxygen during the formation of the first Al-containing film 33 was 8.33×10⁻⁸ m³/s. The protective film 40 including a multilayer structure in which a plurality of SiO₂ layers and a plurality of Ta₂O₅ layers were alternately layered was formed on the light reflection side end surface 15.

Thereafter, the bar was cleaved in a direction perpendicular to the cleavage plane to obtain the nitride semiconductor laser element 10 of Example.

In the nitride semiconductor laser element 10 of Example and the nitride semiconductor laser elements of Comparative Example and Reference Examples 1 to 4, each protective film 30 was formed having the constitution shown in Table 1. In each of these nitride semiconductor laser elements, the reflectance of the protective film 30 with respect to the oscillation wavelength of the nitride semiconductor laser element 10 was about 15%.

TABLE 1

| | | | | | Reference | Reference | Reference | Reference |
|---|---|---|---|---|---|---|---|---|
| | | | | Comparative | Example | Example | Example | Example |
| | | Example | | Example | 1 | 2 | 3 | 4 |
| First film | Al₂O₃ | 5 | nm | 5 nm | 5 nm | 5 nm | 5 nm | 5 nm |
| Second film | AlN | 47 | nm | — | 17 nm | 17 nm | 17 nm | 47 nm |
| First | Al₂O₃ | 132 | nm | 147 nm | 118 nm | 250 nm | 118 nm | 132 nm |
| Al-containing film | | | | | | | | |
| First | SiO₂ | 75 | nm | — | — | — | 150 nm | 75 nm |
| silicon oxide film | | | | | | | | |
| Second | Al₂O₃ | 66 | nm | — | — | — | — | 66 nm |
| Al-containing film | | | | | | | | |
| Second | SiO₂ | 149 | nm | — | — | — | — | — |
| silicon oxide film | | | | | | | | |

Eight nitride semiconductor laser elements 10 of Example and eight nitride semiconductor laser elements of each of Comparative Example and Reference Examples 1 to 4 were produced, and a life test was performed by continuous oscillation at a light density of about 50 MW/cm² for about 7 months to measure the number of sudden deaths. In each case, the test was terminated when it was confirmed that the number of sudden deaths was more than half, that is, when at least five sudden deaths were confirmed.

As a result, the test was continued until the end of the test period in Example and Reference Example 4, and in the order of Comparative Example, Reference Example 1, Reference Example 2, and Reference Example 3, the number of sudden deaths was confirmed to reach more than half before the end of the test period, and the test was terminated. The number of sudden deaths at the end of the test period was 1 in Example and 2 in Reference Example 4. Among the nitride semiconductor laser element 10 of Example and the nitride semiconductor laser elements of Comparative Example and Reference Examples 1 to 4, the time from the start of the life test until the sudden death of the first one was the longest in the nitride semiconductor laser element 10 of Example.

From these results, it was confirmed that, by providing the first film 31, the second film 32, the first Al-containing film 33, the first silicon oxide film 34, the second Al-containing film 35, and the second silicon oxide film 36, the likelihood of occurrence of catastrophic optical damage of the nitride semiconductor laser element 10 was able to be reduced. In addition, this indicated that the lifetime of the nitride semiconductor laser element 10 was able to be extended.

What is claimed is:

1. A nitride semiconductor laser element comprising:
a nitride semiconductor layered body including
a first nitride semiconductor layer having a first conductivity type,
a second nitride semiconductor layer having a second conductivity type as a conductivity type different from the first conductivity type, and
an active layer disposed between the first nitride semiconductor layer and the second nitride semiconductor layer,
the nitride semiconductor layered body defining a light emission side end surface and a light reflection side end surface that intersect with a surface of the active layer on a side of the second nitride semiconductor layer; and
a protective film arranged on the light emission side end surface, the protective film including, in the order from a side of the light emission side end surface,
a first film made of an oxide film containing aluminum and/or gallium,
a second film made of a nitride film,
a first Al-containing film containing aluminum and oxygen,
a first silicon oxide film,
a second Al-containing film containing aluminum and oxygen, and
a second silicon oxide film,
the second silicon oxide film being disposed on an outermost side of the protective film.

2. The nitride semiconductor laser element according to claim 1, wherein
each of the first Al-containing film and the second Al-containing film is an oxide film containing aluminum.

3. The nitride semiconductor laser element according to claim 1, wherein
each of the first Al-containing film and the second Al-containing film is a film of an amorphous structure or a film including an amorphous structure and a crystal structure.

4. The nitride semiconductor laser element according to claim 1, wherein
the first Al-containing film has a thickness larger than a thickness of the second Al-containing film, and
the first silicon oxide film has a thickness smaller than a thickness of the second silicon oxide film.

5. The nitride semiconductor laser element according to claim 1, wherein
each of the first film and the second film is a crystalline film.

6. The nitride semiconductor laser element according to claim 1, wherein
the first film has a thickness of less than 10 nm.

7. The nitride semiconductor laser element according to claim 1, wherein
an axis orientation of a crystal in a region of the second film adjacent to the active layer is the same as an axis orientation of a crystal in a region of the second film adjacent to the first nitride semiconductor layer and/or a region of the second film adjacent to the second nitride semiconductor layer.

8. The nitride semiconductor laser element according to claim 1, further comprising
an additional protective film arranged on the light reflection side end surface.

9. The nitride semiconductor laser element according to claim 8, wherein
the additional protective film has a film structure that is the same as a film structure of the protective film arranged on the light emission side end surface.

10. The nitride semiconductor laser element according to claim 8, wherein
the additional protective film has a film structure that is different from a film structure of the protective film arranged on the light emission side end surface.

11. The nitride semiconductor laser element according to claim 10, wherein
the additional protective film includes, in the order from a side of the light reflection side end surface,
a first portion formed of one or more films including a film having a relatively low refractive index and a film having a relatively high refractive index, and
a second portion formed by alternately disposing relatively high refractive index films and relatively low refractive index films.
